(19) United States
(12) Patent Application Publication
(10) Pub. No.: US 2025/0272126 A1
(43) Pub. Date: Aug. 28, 2025

(54) Logic Level Metric Count Extraction from Emulation Hardware

(71) Applicant: Synopsys, Inc., Sunnyvale, CA (US)

(72) Inventors: Beshara George Elmufdi, Santa Clara, CA (US); Anup Kumar Sultania, Columbia, MD (US)

(21) Appl. No.: 18/590,528

(22) Filed: Feb. 28, 2024

(51) Int. Cl. G06F 9/455

(52) U.S. Cl. CPC G06F 9/45504

(57) ABSTRACT

A processing device may add at least one logic level metric count module to a circuit design, load the circuit design into an emulation system, and apply an emulation workload to the emulation system to which the circuit design is loaded. The processing device may then obtain at least one logic level metric count from the at least one logic level metric count module, the at least one logic level metric count associated with at least a portion of the emulation workload, and present at least one power utilization estimate for the circuit design, where the at least one power utilization estimate for the circuit design is based upon the at least one logic level metric count.

### TECHNICAL FIELD

The present disclosure relates to circuit emulation and programmable logic devices.

### BACKGROUND

Emulation systems, or emulators, may include scalable hardware units, where each unit may include programmable logic blocks interconnected through high-speed links. The programmable logic blocks may include elements such as registers, gates, and memory primitives. These elements may be interconnected by switches that can be configured to achieve connectivity functions between elements. In addition, the gates can be programmed to emulate any Boolean logic function of finite variables. An emulation compiler may be tasked with mapping an input register transfer level (RTL) design onto a target emulation system, such that the target implementation is optimized for emulation throughput and capacity utilization of emulator system resources.

### BRIEF DESCRIPTION OF THE DRAWINGS

The disclosure will be understood more fully from the detailed description given below and from the accompanying figures of embodiments of the present disclosure. The figures are used to provide knowledge and understanding of embodiments of the present disclosure and do not limit the scope of the present disclosure to these specific embodiments. Furthermore, the figures are not necessarily drawn to scale.

FIG. 1 illustrates an example logic level metric count module/circuit of the present disclosure.

FIG. 2 illustrates an example of using multiple logic level metric count modules within an emulation system, in accordance with the present disclosure.

FIG. 3 illustrates two examples of aggregated logic level metric count modules, in accordance with the present disclosure.

FIG. 4 illustrates an example emulation system, including several programmable logic devices, which is configured to emulate a circuit design in accordance with the present disclosure.

FIG. 5 illustrates a flowchart of an example method for structuring an emulation system to include a coalesced memory implementation using a memory primitive of a memory primitive type to emulate selected logical memories.

FIG. 6 depicts a flowchart of various processes used during the design and manufacture of an integrated circuit in accordance with some embodiments of the present disclosure.

FIG. 7 depicts a diagram of an example emulation system in accordance with some embodiments of the present disclosure.

FIG. 8 depicts a diagram of an example computer system in which embodiments of the present disclosure may operate.

### DETAILED DESCRIPTION

Aspects of the present disclosure relate to circuit emulation, e.g., within a circuit design process. For instance, a circuit design may be emulated using programmable logic to verify the functionality of the circuit design. An emulation compiler may map an input circuit design (e.g., a register transfer level (RTL) design) onto a target emulator (e.g., a programmable logic device/system), such that the target implementation is optimized for emulation-throughput and capacity utilization of the emulator's resources.

In one example, an emulator may be made of scalable hardware units (e.g., programmable gate arrays, or the like, such as field-programmable gate arrays (FPGAs), etc.), where each unit is a collection of programmable logic blocks interconnected through high-speed interconnection links. The programmable logic blocks may include elements such as registers, gates, and memory primitives. In one example, these elements may be interconnected by switches, which can be configured to achieve any connectivity function between elements. Likewise, the gates can be programmed to emulate any Boolean logic function of finite variables. The memory primitives may include monolithic blocks of random-access memory (termed Block-RAM) or look-up table RAM (LUTRAM). Hardware units can be added or removed from an emulator based on the RTL-design logic and/or the quality of mapping generated by the emulation compiler. The emulation compiler is expected to make optimal use (e.g., a desired use) of all the available elements (registers, gates, and memory primitives) while mapping an RTL-design onto the emulator.

One aspect of electronic circuit design, e.g., system on chip (SoC) development, is power estimation. In many cases, SoC designs have specific power usage targets to achieve. Circuit developers may use simulation and emulation to run a circuit design with software programs that are the same as or close to those programs that may be encountered according to the intended use of the electronic circuit design. These programs, which may be referred to as workloads, may be used to obtain more realistic power information in a power estimation process. To reduce the amount of time for power estimation, emulation may be used, where the circuit design being profiled is emulated in emulation hardware.

In one approach, emulation hardware is used to extract waveforms from the design. These waveforms can be used for software-based power analysis tools to extract toggle information. From the toggle information, power consumption can be computed by power estimation software. However, despite using hardware emulation in such an approach, the actual time to obtain power estimation information is relatively slow. For instance, the general performance may be less than 1 KHz. In contrast, examples of the present disclosure may modify/supplement an emulated circuit design to collect and compute logic level metric counts, such as toggle counts (TC) or counts of logic level high, which may be referred to as a T1 count (as well as counts of logic level low) for nodes in the circuit design using the capabilities of the emulation hardware. The emulation hardware computing the logic level metric counts (e.g., TC and/or T1 count) significantly increases the speed, e.g., versus a software-based approach. This further enables a circuit designer to run long software workloads on the emulated design. It is therefore possible to characterize much longer runs for power estimation.

In one example, the present disclosure may include one or more circuits or module(s) instantiated within the emulation hardware, e.g., within one or more programmable logic devices, to obtain logic level metric counts for nodes in the circuit design, and to then transmit such information to a workstation. In one example, the counter module(s)/circuit(s) may be configured to detect toggle counts (TCs). In another example, the counter module(s)/circuit(s) may be configured to detect signals at monitored nodes remaining constant, e.g., time-at-1 (T1). The module(s) may perform a certain number of logic level metric counts within one emulation cycle. In addition, the module(s) may include shared circuitry for logic level metric counts across multiple nodes, thus reducing the overhead of the module(s). As noted above, the count module(s)/circuit(s) may be added to the design under test (DUT) in the emulator/emulation system. For instance, a DUT may be loaded to one or more FPGAs (or other PLDs). Along with the DUT, the counter module(s)/circuit(s) may be instantiated in the FPGA(s) to collect logic level metric counts (toggles and/or T1) and to communicate to a management system that may further process the results.

In one example, two modes of power analysis may proceed from the collected counts. For instance, both TC and T1 counts may be used for average mode power estimation. Alternatively, or in addition, TC alone may be used to generate estimated weighted power based on a flop's cone of influence. To capture both TC and T1, a memory allocation of the PLD may double (e.g., for two separate counters for TC and T1 count, respectively). However, other resources may be shared. To further illustrate, for average mode power computation, TC can be converted to an activity rate or toggle rate (TR)=TC/Emulation_Duration. Similarly, T1 can be converted to probability-of-1 (Prob)=T1/Emulation_Duration. Toggle rate and probability may then be annotated onto various signals, such as sequential outputs, power inputs (PI), bounding box outputs, and so forth. In one example, statistical propagation may be applied to estimate TR and Prob for various signals, following which average mode power may be computed for the circuit design.

For power window detection, the present disclosure may generate TC and T1 for various time slices/time windows, and may generate average mode power for each slice. Over numerous cycles (e.g., billions), average power for each slice may provide a high-level snapshot of slices with high power consumption (and/or of slices with low power consumption, average power consumption, etc.). As such, a circuit designer can use power window detection to identify various power windows of interest, e.g., to match to various events in the software workload, etc. To further illustrate, average power may comprise two components-dynamic power and static (leakage) power. TC may be used to compute dynamic power and T1 may be used to compute static power. In one example, dynamic power of a net may be determined via the formula 0.5*C*V\hat{ }2*F, where C is the capacitance of the circuit design, which may be obtained from design parasitic file, V is the operating voltage of the design, and F is the toggle rate (TR). Similarly, dynamic power of the pins of a cell may be computed using information present in the technology library, which may be in the form of a look-up-table for each input-pin to output-pin of a cell. Slew and capacitance of the input pin are the index into the look-up table. Slew may be computed by using the timing information present in the technology library and the design structure. Capacitance may be obtained from the design parasitic file. Using this information, the internal power per toggle for each pin of the cell may be computed. Average power for each pin may be computed by multiplying with toggle-rate of the pin. Accordingly, average dynamic power of the entire circuit design may be computed by adding all the net and pin powers.

In addition, static (leakage) power data may be present in the technology library in the form of various input state condition. For example, for a 2-input AND gate, there are four input combinations: A=B=1, A=B=0, A=1 B=0, A=0 B=1. Leakage for each of the input state conditions may be specified. T1 may then be used to determine the probabilities of A and B. Next, using the input pin probabilities, the probabilities of each input state condition may be determined. Next, multiplying each individual state condition probability with its corresponding leakage power, and summing the results provides the leakage power of the cell. Accordingly, leakage power of all the cells may be summed to compute the average leakage (static) power of entire circuit design.

Notably, examples of the present disclosure may provide a performance rate of approximately 200 KHz. In contrast, other hardware emulation approaches that extract waveforms from the emulator at a maximum rate of approximately 45 kilohertz (KHz) and convert the waveforms to toggles at a maximum rate of approximately 650 Hz (the total runtime time being the sum of the time to complete these two phases). Thus, examples of the present disclosure provide an approximately 380-fold increase in speed for the same power estimation workloads as compared to prior hardware-based approaches. To further illustrate, an emulation run that takes one (1) hour using an example of the present disclosure, may take at least 380 hours (approximately 16 days) with previous methodologies, which may be an unreasonable amount of time to complete power estimation for a single workload. In addition, considering a scenario in which there may be several different workloads, the advantages over previous methodologies are even more substantial.

It should be noted that a workload may be a software program that is used to measure performance of a circuit design/model via the emulation hardware. For instance, different workloads may be applied in hardware emulation for simulating streaming video, engaging in social media, etc. Workloads can thus be run to determine the processor and memory requirements, e.g., in addition to power, etc. For a 1 GHz processor, a one second run of workload may span 1 billion cycles. To simulate playing a video game for one minute, this corresponds to 60 billion clock cycles. However, for one second at 1 GHz, a 200 KHz emulation may take 5,000 seconds (approximately 2 hours of emulation for just 1 second of real-time workload).

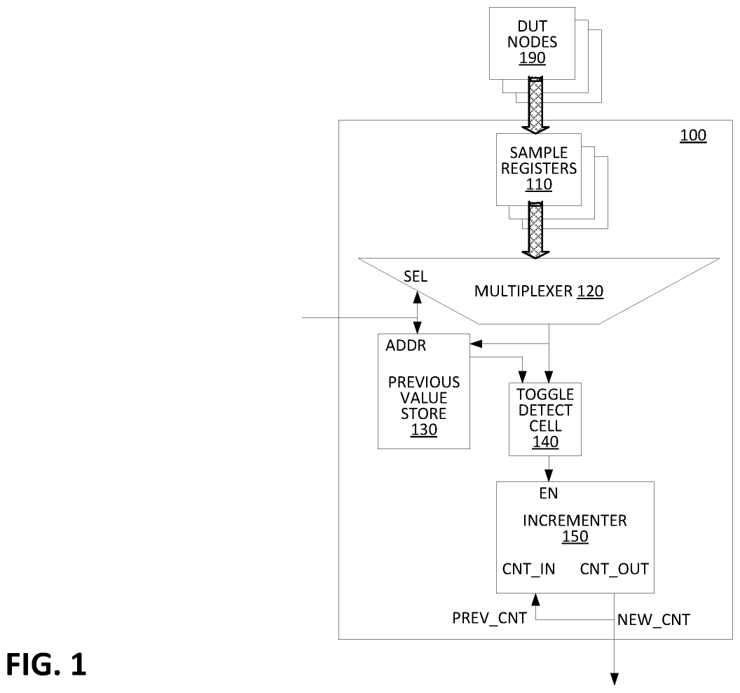

Technical advantages of the present disclosure include, but are not limited to improved power estimation for circuit designs, including significantly faster power estimation as compared to other approaches and/or with capacity for increased workload volume in a same duration of time. Examples of the present disclosure also provide an improved computing device or system implementing examples of the present disclosure. For instance, a computing device may add counter module(s) to a circuit design, and may compile and load such a circuit design to an emulation system to provide a significantly faster hardware-based power estimation process. In addition, an emulation process is improved insofar as examples of the present disclosure may add a hardware-based logic level metric count functionality, which may be activated and used in connection with various test workloads. In one example, an emulation system is also improved by enhancing the capability of the emulation system to provide hardware-based logic level metric count functionality, e.g., in addition to other capabilities of the emulation system. These and other aspects of the present disclosure are discussed in greater detail below in connection with the examples of FIGS. 1-8.

In an illustrative example of FIG. 1, a first example module 100, e.g., a counter module/circuit of the present disclosure, may include a plurality of sample registers 110 associated with a plurality of nodes 190 of a circuit design, or design under test (DUT). Each of the sample registers 110 may sample a logic value from a corresponding one of the nodes 190 in the DUT, once per emulation clock cycle, and may place the sampled/recorded value on the output until the logic value is updated at the next sampling in the next emulation clock cycle.

The module 100 includes an incrementer 150, which in the present example may also be referred to as a toggle incrementer circuit (TIC). In the example of FIG. 1, the module 100 may sample and compute toggles for up to 512 nodes at a time (e.g., of the nodes 190). For instance, the module 100 may include a multiplexer 120, which may select among the nodes 190 for counting toggles via the sample registers 110. Notably, the multiplexer 120 (e.g., in one example a 512:1 multiplexer) may run at a significantly faster clock speed than the emulation clock (e.g., at least 512 times faster), such that the multiplexer 120 can select all 512 signals within one emulation cycle, one at a time. For instance, the multiplexer 120 may serially select sample registers 110 to detect toggles for 512 of the nodes 190 per emulation clock cycle. To further illustrate, the module 100 may run at 100 MHz native speed, or polling speed to cycle through 512 samples in 5120 ns (195 KHz), where the emulation clock cycle for the DUT may run up to 195 KHz.

Module 100 further includes a storage element, previous value store 130, to store the previous value from each of the sample registers 110. For instance, previous value store 130 maintains the logic values from each of the sample registers 110 from the previous emulation clock cycle so that these logic values can be compared to the logic values from the current emulation clock cycle to detect if and when toggles occur at the nodes 190. In this regard, a toggle detect cell 140, e.g., an edge detector or edge detector circuit, may be used to indicate that a selected one of the nodes 190 has toggled, e.g., if a previous value is not equal to a current value for a given node 190 and/or an associated one of sample registers 110. For instance, the previous value may come from the previous value store 130. In one example, the edge detector may be two-input look-up table (LUT) to detect an edge (or level signal, depending upon the particular function). In one example, an address select input (ADDR) of the previous value store 130 may be used to select a particular address (e.g., a bit/element) that stores the previous value corresponding to the given node 190 and/or the associated one of sample registers 110, where the previous value stored at the selected address (e.g., a logic one or zero) is passed to the toggle detect cell 140. A second input of the toggle detect cell 140 may be the output of the multiplexer 120. Notably, the multiplexer 120 may include a selection input (SEL) to select to pass the logic value from a corresponding one of the sample registers 110 to the output of the multiplexer 120.

In addition, the module 100 includes a counter, incrementer 150, that increments the previous toggle count if a selected one of nodes 190 has toggled. In one example, the output of incrementer 150 (NEW_COUNT) at output port CNT_OUT is fed-back as an input (PREV_COUNT) to the incrementer 150 at an input port (CNT_IN). When a toggle is detected at toggle detect cell 140, the enable input (EN) of incrementer 150 may be logic value one (1) in which case, the incrementer 150 is configured to increase the stored value in the incrementer 150 by one. For instance, a new count value (NEW_COUNT) may be equal to PREV_COUNT+1 if EN is logic high. Otherwise, if EN is logic low, then NEW_COUNT may be equal to PREV_COUNT. In various examples, the incrementer 150 may be configured for different use cases. For example, the width of the incrementer 150, in bits, may determine how many cycles worth of toggle data it can store. In one example, incrementer 150 may be a saturation counter, which may count up to a specific maximum value (e.g., no overflow) and then reset. In one example, the output port CNT_OUT of incrementer 150 may have a width such that a sufficient number of digits may be used to store values up to a maximum selected value to be stored in the incrementer 150.

In one example, the NEW_COUNT value may be fed to an external storage element (not shown), where it may be stored as a current/previous toggle count for the nodes 190. For instance, the external storage element may be instantiated on the same programmable logic device (PLD) as the module 100 and/or on a different PLD of the emulation system. In addition, the module 100, e.g., a toggle detection/counter circuit, may be replicated many times with the emulation system, e.g., within one or more programmable logic devices thereof, to account for all the nodes in the DUT to be counted.

It should also be noted FIG. 1 illustrates an example module 100 for detecting and counting toggles within a portion of a DUT (e.g., up to 512 nodes thereof). However, in another example, the present disclosure may include a similar module for counting logic level high at nodes within the DUT, e.g., nodes 190. For instance, in such case, a module to detect logic level high may omit the previous value store 130, toggle detect cell 140, and the connections between these and other elements. In addition, the output of the multiplexer 120 may feed directly to the enable input EN of the incrementer 150. Likewise, in one example, a module may include shared elements for both toggle detection/count and logic high detection/count. For instance, in such an example, the module 100 may include all of the elements as illustrated in FIG. 1, and may further include a second incrementer that is fed directly from the output of multiplexer 120. In addition, in such an example, the output of the multiplexer 120 may be split to feed the previous value store 130, the toggle detect cell 140 and the additional incrementer for counting a number of logic high values exhibited by nodes 190/sample registers 110. As such, toggle detection/count and logic high detection/count operations may proceed in parallel.

It should also be noted that FIG. 1 illustrates just one example of a toggle detection/counting module/circuit, and that other, further, and different examples of the present disclosure may provide a module/circuit for logic level metric counting with more or less elements, with different elements, and so forth. For instance, as just one additional example, a circuit for logic level low detection/counting may be represented by the module 100 without the previous value store 130 and toggle detect cell 140, where the output of the multiplexer 120 may feed an inverter, and where the inverter output may feed the enable input EN of the incrementer 150, e.g., to count logic level low, e.g., logic zero (0). Thus, these and other modifications are all contemplated within the scope of the present disclosure.

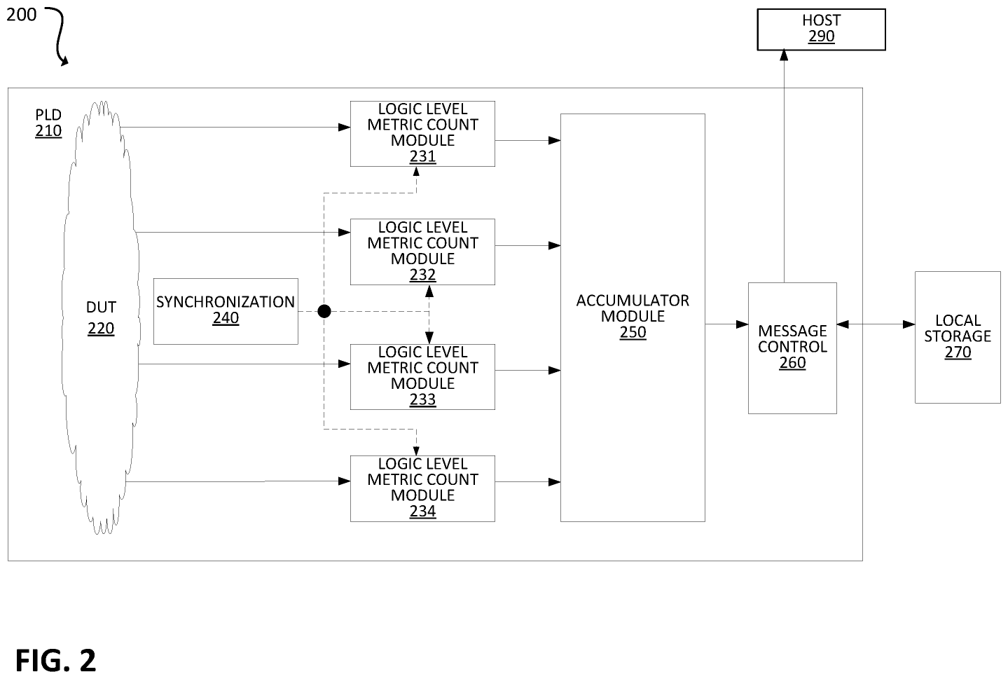

FIG. 2 illustrates an example of using multiple logic level metric count modules 231-234 within an emulation system 200. For instance, emulation system 200 may include at least a first programmable logic device (PLD) 210 (e.g., an FPGA or the like). A design under test (DUT) 220 may be compiled and loaded into the PLD 210. In other words, the PLD 210 is programmed/configured to replicate the elements and operations of a circuit design as DUT 220, e.g., including a plurality of nodes. The PLD 210 may further include a number of logic level metric count modules 231-234, which may each correspond to logic level metric count module/circuit, such as module 100 of FIG. 1, or the like. A synchronization unit 240 may provide a sampling/polling/count clock by which all of the logic level metric count modules 231-234 may operate, while the DUT 220 may operate according to an emulation clock at a lower frequency. For instance, the sampling/polling/count clock may operate at a frequency that is 512 times or greater than the frequency of the emulation clock (e.g., using 512:1 multiplexers within the logic level metric count modules 231-234).

The accumulator module 250 may collect and aggregate the logic level metric counts (e.g., toggle counts (TCs) and or T1 counts) from the level metric count modules 231-234. In one example, the accumulator module 250 may further create packets to send to a management station/workstation, host 290. For instance, the packets may include aggregated logic level metric counts for one or more workloads, for one or more time slices within a workload, etc.

The accumulator module 250 may map the data from the logic level metric count modules 231-234 to the corresponding emulation clock cycles. Using this information, the accumulator module 250 may gather the received logic level metric count information into a local buffer. This information can then be aggregated into a format that the host 290, may utilize (e.g., T1 count information and/or toggle counts per time slice, etc.). In one example, the accumulator module 250 may also packetize this data such that the message control module 260 can communicate the data via a channel to the host 290 or optionally buffer data locally in local storage 270, e.g., a local cache, until the host 290 is ready to receive the data. In one example, the accumulator module 250 may perform additional processing on the logic level metric count information. For example the data can be marked as “interesting” or “not interesting.” An “interesting” set of data (T1 count(s) and/or toggle count(s)) are ones that have been indicated or flagged as containing information to be stored for later processing. This data may be transmitted to the message control module 260 to ensure this storage request is met. A “not interesting” set of T1 count(s) and/or toggle count(s) are those with no special indication or flag associated therewith. This data may be stored or discarded based on a pre-defined policy, or the like.

Deciding on which data is “interesting” or “not interesting” may vary from emulation model run to emulation model run and/or from workload to workload. There are various external mechanisms that can be used for this purpose. For instance, in one example, the accumulator module 250 may have an input signal for events, or triggers, which may have one value when the data being received from the logic level metric count modules 231-234 is “interesting” and another value when it is “not interesting.” The accumulator module 250 may be further configured with one or more rules to decide what to do with the “not interesting” data (e.g., discard it, send it out, only send it out under certain conditions, etc.). The event/trigger input may be used to flag “interesting” and “not interesting” data based on simple or complex settings and algorithms from one or more sources internal to the PLD 210 and/or external, such as from the host 290, e.g., from a user input or other automated processes. To further illustrate, a user or other automated process may indicate that data is “interesting” when temporally correlated to a particular part of an emulation model run, when a toggle count and/or T1 count exceeds a threshold, or thresholds, when an error indicator or other indicator is received from one or more debug modules or other components of the circuit design, and so forth. Alternatively, or in addition, a user or other automated process may indicate that data is “not interesting” for one or more time blocks within an emulation model run. For instance, the initial cycles/time block of an emulation model run may be to place the circuit in a desired state, where the circuit may then be further tested through more rigorous processing tasks in subsequent cycles/time blocks of the emulation model run. Thus, the initialization portions of the emulation model run may be designated as “not interesting”. Various other indicators of “interesting” and/or “not interesting” data of the same or a similar nature may be programmed into the accumulator module 250, may be programmed into one or more other modules of the circuit design, which may be configured to signal to the accumulator module 250 when “interesting” condition(s) (or “not interesting” conditions) is/are detected, and/or may be indicated during an emulation model run via an external input, e.g., from a user or from another system external to the PLD 210.

In one example, the PLD 210 may further be configured to include a message control module 260, which may manage a communication channel to host 290, or optionally a local memory 270 that can be used as a cache. For instance, the message control module 260 may temporarily store quantities of logic level metric count data, e.g., logic level metric counts, including TC and T1 counts, over various time slices for one or more workloads. In addition, the message control module 260 may retrieve any such data and transmit to the host 290 or other entities upon request. For example, the message control module 260 may use local storage 270 to hold data until the host 290 is no longer busy and can receive the data. Optionally if no local storage is available, the message control module 260 may signal to the rest of the emulation to stop until the host 290 is able to consume the data that is to be transmitted.

In one example, the present disclosure may also include software aspects to facilitate collection of logic level metric counts, for power estimation, and so forth. For instance, the host 290 may program the accumulator module 250 with desired settings. These may include indicating how many cycles to accumulate data for, which conditions to store or send the logic level metric count data, etc. The host 290 may also manage the data being produced during a workload/emulation run. For instance, the host 290 may receive the data, and may store and/or process the data in order to not stall the emulation run.

In one example, the host 290 may also control the running of the emulator/emulation system. For instance, in the case where a large volume of logic level metric count data is to be moved from the PLD 210 to another location, such as to a data storage device, then the host 290 may manage starting and stopping of the emulation clock of PLD 210 to permit the data offloading process. To further illustrate, the host 290 may set-up the logic level metric count logic, e.g., adding logic to the circuit design for purposes of logic level metric count gathering. In addition, the host 290 may indicate how many cycles worth of logic level metric counts to accumulate. In addition, the host 290 may indicate filtering and trigger settings for the accumulator module 250.

During an emulation run, the host 290 may further enable the logic level metric count logic, e.g., one or more logic level metric count modules 231-234 instantiated on the emulation hardware of PLD 210. The host 290 may then indicate a workload run on the emulated design, DUT 220, for a requested number of emulation cycles. While running, the host 290 may assemble information coming from all sources in the emulation system 200 and may perform power computation/estimation. For example, the host 290 may use information on the circuit design and the received logic level metric count data to calculate and provide power information to a user and/or to one or more other automated systems for further analysis. In one example, the host 290 may also generate and display power consumption visualizations, such as graphs of power consumption over time. It should also be noted that FIG. 2 illustrates just one example of an emulation system 200 that is configured to include logic level metric count modules 231-234, and that other, further, and different examples of the present disclosure may provide an emulation system with more or less modules, with different elements, and so forth.

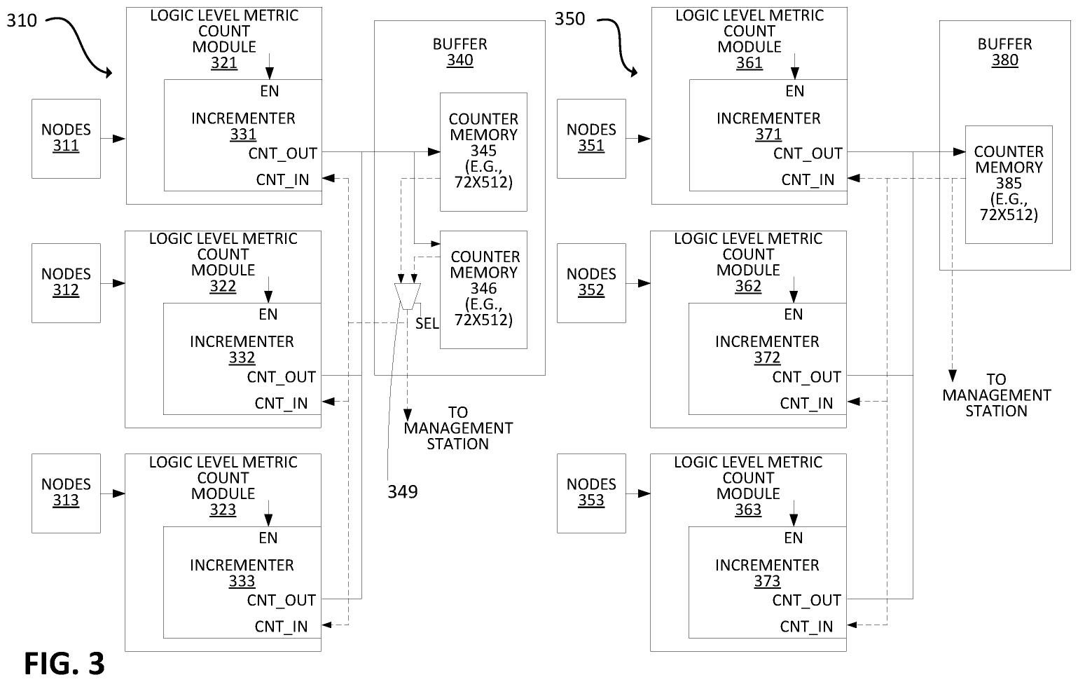

FIG. 3 illustrates two examples of aggregated logic level metric count modules, aggregated modules 310 and 350, in accordance with the present disclosure. For instance, aggregated module 310 may include logic level metric count modules 321-323, which may store logic level metric counts for respective sets of nodes 311-313, e.g., in the respective incrementers 331-333, e.g., incrementer circuits. For instance, each of logic level metric count modules 321-323 may represent an instance of module 100 of FIG. 1, or the like. For ease of illustration, not all of the components within the logic level metric count modules 321-323 are shown. As illustrated in FIG. 3, aggregated module 310 may also include a buffer 340, which may include two counter memories 345 and 346. In this case, the buffer 340 may be referred to as a ping-pong buffer, and may utilize one of the counter memories 345-346 as a live counter to accumulate the logic level metric counts from the respective incrementers 331-333, while using the other of the counter memories 345-346 as a transmission buffer, e.g., to offload to a management station/host.

For example, the incrementers 331-333 may operate independently to count logic level metrics (e.g., TC and or T1 counts) over several emulation cycles for all the nodes 311-313 attached to the respective logic level metric count modules 321-323. The logic level counts may be periodically offloaded to a live one of counter memories 345-346. The live one of counter memories 345-346 may be read to retrieve a previous count value for each node and then written to store the updated current count value for each of modules 321-323. Once a certain number of emulation cycles have elapsed, which can be determined automatically by the circuitry or programmed by a user, the live counter memory may become the transmit counter memory. This transmit counter memory may then be read and the values transmitted to a management station/host. For instance, in one example, the aggregated module 310 may represent the logic level metric count modules 231-234 and the accumulator 250 of FIG. 2. Accordingly, at the same time one of counter memories 345-346 described above is sending data for analysis to the management station, while the other one of counter memories 345-346 may become the live counter memory, and so on for additional blocks of emulation clock cycles. Thus, the buffer 340 is continuously counting on one of the counter memories 345-346 and transmitting count values on the other one of the counter memories 345-346, thereby maintaining high system throughput. In one example, the buffer 340 may include a selection module 349 with a select line via which the live and transmit counter memories may be changed.

In a second example illustrated in FIG. 3, aggregated module 350 may include a single memory buffer implementation. For instance, aggregated module 350 may include the same or similar components as aggregated module 310, e.g., logic level metric count modules 361-363, including incrementers 371-373, and assigned to respective sets of nodes 351-353. As in the preceding example, not all of the components within the logic level metric count modules 361-363 are shown. In this case, aggregated module 350 includes a buffer 380 having a single counter memory 385. Notably, this implementation provides a more compact module/circuit and less expensive implementation, since only one memory is used in the buffer 380. However, the aggregated module 350 may provide somewhat reduced performance as compared to aggregated module 310 insofar as the emulation clock may be stopped in order to offload the counter memory 385, e.g., to a management station or the like. Clocking of the emulation system may be resumed once the data in the memory 385 has been unloaded.

To further illustrate, with respect to the aggregated module 310, the counter memories 345 and 346 may be two, block random access memories (BRAMs) (e.g., with dimensions of 72×512). The aggregated module 310 may support approximately 1,500 nodes using three 512:1 multiplexers (e.g., one for each of logic level metric count modules 321-323), and 24 look-up table random access memories (LUTRAMs) (e.g., 1×64 LUTRAMs, 8 for each of the logic level metric count modules 321-323), to implement previous value stores, such as previous value store 130 illustrated in FIG. 1. In addition, aggregated module 310 may use three 18-bit counters for the incrementers 331-333.

Aggregated module 350 may utilize a similar set of programmable logic device (PLD) building blocks, such as three 512:1 multiplexers (e.g., one for each of logic level metric count modules 361-363), and 24 look-up table random access memories (LUTRAMs) (e.g., 1×64 LUTRAMs, 8 for each of the logic level metric count modules 361-363), to implement previous value stores, such as previous value store 130 illustrated in FIG. 1). In addition, aggregated module 350 may use three 18-bit counters for the incrementers 371-373. However, aggregated module may use a single BRAM (e.g., with dimensions 72×512) for buffer 380.

It should also be noted that FIG. 3 illustrates just two example aggregated modules, and that other, further, and different examples of the present disclosure may provide aggregated modules with more or less elements, with different elements, and so forth. For instance, in an example with four incrementers and a ping-pong buffer, an aggregated module may include four 512:1 multiplexers capable of computing counts for approximately 2,000 nodes in 512 cycles, two BRAM (72×512) (e.g., for the ping-pong buffer), 32 LUTRAM (4×8=32 LUTRAM of dimensions 1×64) and four 18-bit counters. In another example, with four incrementers and a singular buffer, an aggregated module may include four 512:1 multiplexers capable of computing counts for approximately 2,000 nodes in 512 cycles, one BRAM (72×512) (e.g., for the ping-pong buffer), 32 LUTRAM (4×8=32 LUTRAM of dimensions 1×64), and four 18-bit counters. In a further example, the aggregated module 310 may include multiple incrementers within each of the logic level metric count modules 321-323, e.g., an incrementer for toggle counts and an incrementer for T1 counts. In such an example, the buffer 340 may include two additional counter memories, e.g., two for toggle count aggregation and two for T1 count aggregation. In another example, the aggregated module 350 may be similarly modified for processing both toggle counts and T1 counts. In each case, for TC and T1 count, the BRAMs needed will be double, but other resources can be shared. For example, for 16K nodes being monitored and a message being sent once every 256K cycles, TC may utilize 16 BRAMs (8×2=16 BRAM of dimensions 72×512). For T1 count another 16 BRAMs of the same dimensions may be used. Thus, these and other modifications are all contemplated within the scope of the present disclosure.

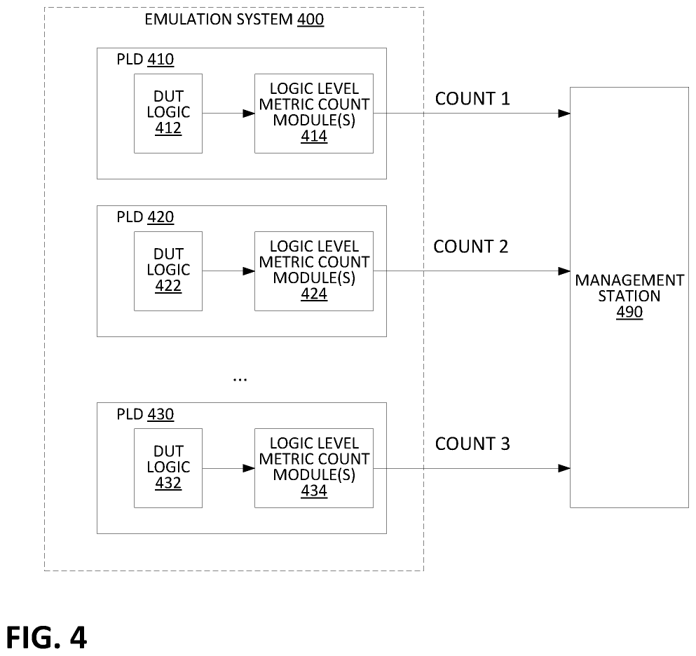

FIG. 4 illustrates an example emulation system 400 including several programmable logic devices (PLDs) 410, 420, and 430 (e.g., FPGAs or the like), that is configured to emulate a circuit design, or design under test (DUT). For instance, aspects of the DUTs (e.g., DUT logic 412, DUT logic 422, and DUT logic 432) may be allocated to different ones of the PLDs 410, 420, and 430. The DUT logic 412, DUT logic 422, and DUT logic 432 may each include multiple nodes that may be monitored by respective logic level metric count module(s) 414, 424, and 434. For instance, logic level metric count module(s) 414 may include one or more logic level metric count modules, such as one or more instances of module 100 illustrated in FIG. 1, or the like (and similarly for logic level metric count module(s) 424 and 434). Alternatively, or in addition, logic level metric count module(s) 414, 424, and 434 may each correspond to an aggregated module, such as illustrated in FIG. 3 or the like. The logic level metric count module(s) 414, 424, and 434 may gather and transmit logic level metric counts (which in one example may include aggregated logic level metric counts from multiple modules) to a management station 490. Thus, the example of FIG. 4 illustrates that as DUT logic 412, 422, and 432 are distributed to different PLDs 410, 420, and 430, respective logic level metric count module(s) 414, 424, and 434 may be similarly distributed therewith. The management station 490 may then compute various additional metrics, such design-wide TCs and or T1 counts, design-wide power consumption estimates, and so forth. Alternatively, or in addition, the management station 490 may compare different aspects of the circuit design that may be segregated into DUT logic 412, 422, and 432, such as identifying different power utilization estimates in different aspects of the circuit design at a same time for a same workload, and so forth. As in the preceding examples, it should also be noted that FIG. 4 illustrates just one example of a distributed emulation system 400 including multiple PLDs 410, 420, and 430, and that other, further, and different examples of the present disclosure may provide a distributed emulation system with more or less PLDs, with different elements, and so forth.

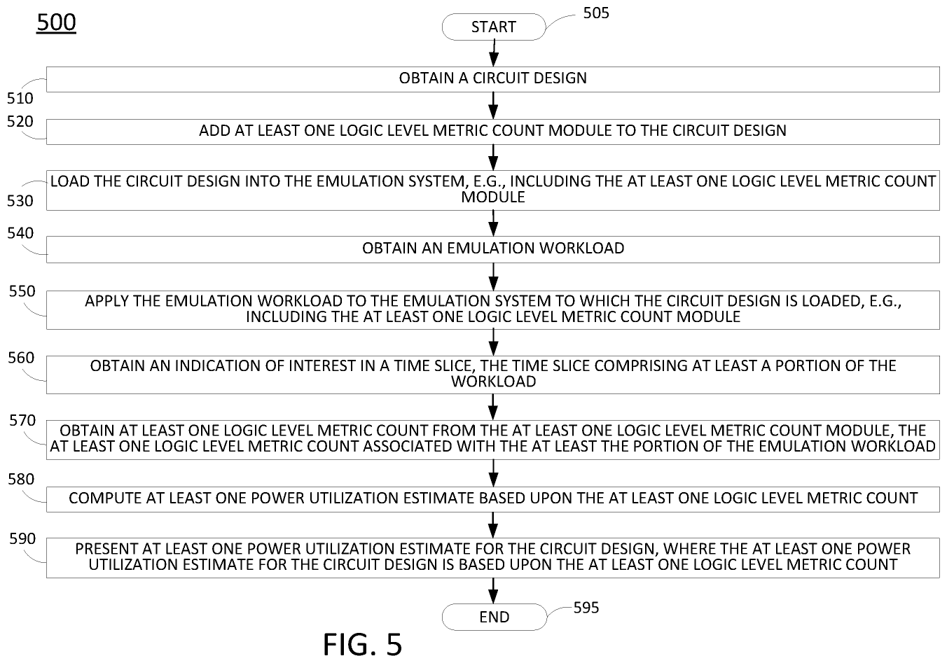

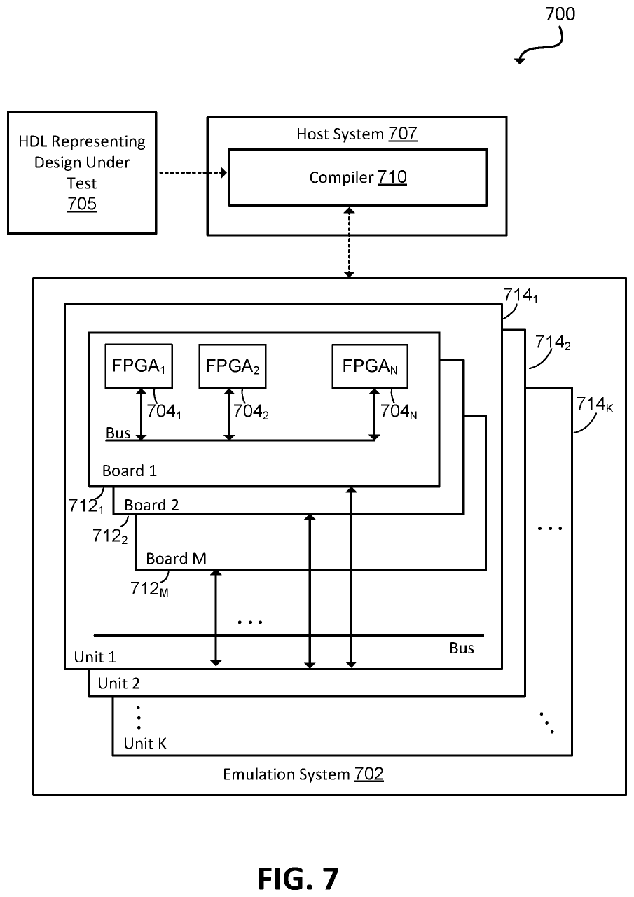

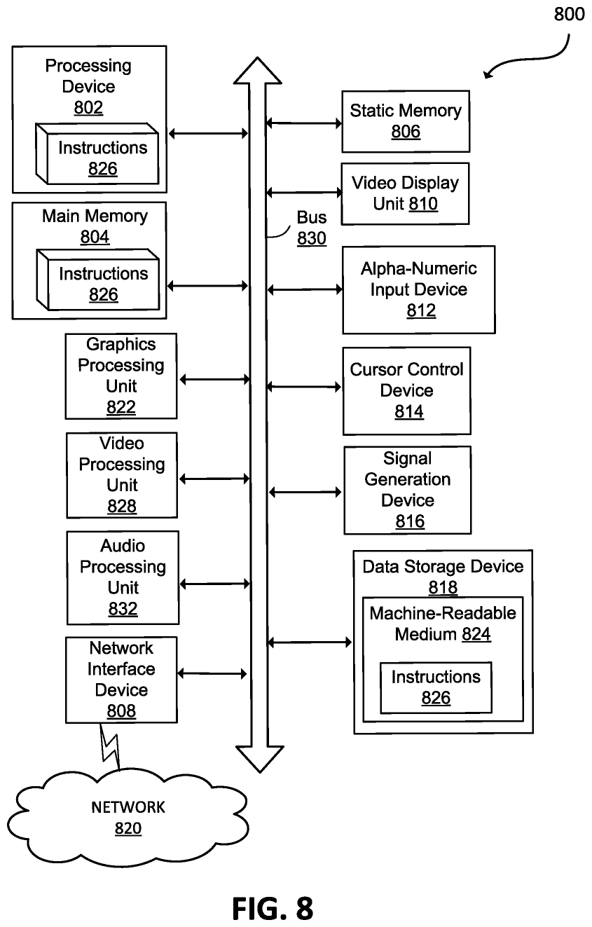

FIG. 5 illustrates a flowchart of an example method 500 for presenting at least one power utilization estimate for a circuit design based upon at least one logic level metric count obtained from at least one logic level metric count module that is added to the circuit design and loaded to an emulation system. In one example, the method 500 may be performed by a computing device or system, e.g., a processing system, or processing device, including at least one processor, a memory storing instructions, which when executed by the at least one processor, cause the processing system to perform operations, etc. For instance, the method 500 may be performed by a processing system including at least one processor, such as host system 707 and/or compiler 710 of FIG. 7, or host system 707 and/or compiler 710 in conjunction with emulation system 702, the computer system 800 of FIG. 8, and/or any one or more components thereof, such as processing device 802, or multiple instances of computer system 800 in communication over one or more networks and operating collectively to perform one or more aspects of the method 500. For illustrative purposes, the method 500 is described in connection with an example performed by a processing system. The method 500 begins in 505 and may proceed to 510.

At 510, the processing system may obtain a circuit design. For instance, the circuit design may include a register transfer level (RTL) design, e.g., an RTL netlist.

At 520, the processing system may add at least one logic level metric count module to the circuit design. For instance, the at least one logic level metric count module may include one or more modules for toggle count and/or T1 count, such as illustrated in FIG. 1 and described above, or the like. For example, the at least one logic level metric count module may be configured to count at least one of the toggle count (TC) of the signals at the one or more nodes of the circuit design or the count of the instances of the signals being at the logic level high (T1 count) at the one or more nodes of the circuit design. Alternatively, or in addition, the at least one logic level metric count module may be an aggregated module, such as aggregated module 310 and/or aggregated module 350 of FIG. 3, and/or a set of aggregated logic level metric count modules, such as logic level metric count modules 414, 424, and 434 of FIG. 4. In one example, 520 may include creating and connecting one or more new netlist artifacts corresponding to the at least one logic level metric count module. For instance, the new netlist artifacts may include memory primitives for one or more incrementers, for one or more previous value stores (e.g., where the logic level metric count module(s) is/are for toggle counts), for one or more buffers, etc., as well as multiplexers, gates, and so forth that may facilitate the operations of the at least one logic level metric count module.

At 530, the processing system may load the circuit design into the emulation system, e.g., including the at least one logic level metric count module. For example, the processing system may include the functionality of an emulation compiler to map an input circuit design (e.g., a register transfer level (RTL) design) onto a target emulator (e.g., a programmable logic device/system), e.g., such that the target implementation is optimized for emulation-throughput and capacity utilization of the emulator's resources. For instance, the processing system may transform specifications written in a description language that represents a DUT to produce data (e.g., binary data) and information that is used to structure the emulation system to emulate the DUT. In addition, the processing system can transform, change, restructure, add new functions to, and/or control the timing of the DUT.

As described above, the at least one logic level metric count module may include a multiplexer having a plurality of inputs for a plurality of sample registers associated with a plurality of nodes of the circuit design and a selection input to select an input of the plurality of inputs to pass to an output of the multiplexer. In addition, the at least one logic level metric count module may include an incrementer unit coupled to the output of the multiplexer, where the incrementer unit increases a count for each polling clock cycle (e.g., per the sampling/polling/count clock of the at least one logic level metric count module) in which the output of the multiplexer is a logic high value. For instance, in such an example, the at least one logic level metric count module may be for collecting and reporting a T1 count. In one example, each sample register may store a value of a respective node of the circuit design for each emulation clock cycle of a plurality of emulation clock cycles of the emulation workload.

In one example, the at least one logic level metric count module may alternatively or additionally include a multiplexer having: a plurality of inputs for a plurality of sample registers associated with a plurality of nodes of the circuit design and a selection line to select an input of the plurality of inputs to pass to an output of the at least one multiplexer for a polling clock cycle. The at least one logic level metric count module may alternatively or additionally include a previous value store coupled to the output of the multiplexer, to store a value of the output of the multiplexer from a current emulation clock cycle until a next emulation clock cycle of a plurality of emulation cycles of the emulation workload. The at least one logic level metric count module may also include a toggle detector having a first input for the output of the multiplexer and a second input for an output of the previous value store, where the toggle detector outputs a logic high value when a first value on the output of the multiplexer is different from a second value on the output of the previous value store. For instance, in one example, the toggle detector may include an edge detector circuit. In addition, the at least one logic level metric count module may further include an incrementer unit coupled to the output of the at least one toggle detector. For instance, the incrementer unit may increase a count for each polling clock cycle in which the output of the toggle detector is a logic high value. In one example, the previous value store may include a number of storage bits that is at least as great as a number of the plurality of inputs of the multiplexer. In one example, the previous value store may include an address select input that is the same as the selection line of the multiplexer. As in the preceding example, each sample register of the plurality of sample registers may store a value of a respective node of the plurality of nodes for each emulation clock cycle of the plurality of emulation clock cycles of the emulation workload.

At 540, the processing system may obtain an emulation workload. For instance, the emulation workload may include one or more programs, applications, and/or data processes, or data sets that simulate one or more programs, applications, and/or data processes.

At 550, the processing system may apply the emulation workload to the emulation system to which the circuit design is loaded, e.g., including the at least one logic level metric count module. For instance, the emulation workload may be applied via input-output pins/ports of the emulation system (e.g., one or more PLDs thereof). Alternatively, or in addition, at least a portion of the emulation workload may be pre-loaded, e.g., into one or more memories of the one or more PLDs, where the workload may be externally activated via one or more instructions, and where the at least the portion of the workload data may be retrieved from the one or more memories in response to the one or more instructions.

At 560, the processing system may obtain an indication of interest in a time slice, the time slice comprising the at least the portion of the workload.

At 570, the processing system may obtain at least one logic level metric count from the at least one logic level metric count module, the at least one logic level metric count associated with at least a portion of the emulation workload. For instance, in one example the at least one logic level metric count may include one or both of: a toggle count of signals at one or more nodes of the circuit design or a count of instances of the signals being at logic level high at the one or more nodes of the circuit design. In one example, the obtaining of the at least one logic level metric count from the at least one logic level metric count module may include offloading the at least one logic level metric count in response to the obtaining of the indication of the interest in the time slice at 560.

At 580, the processing system may compute at least one power utilization estimate based upon the at least one logic level metric count. For instance, as described above, the processing system may compute a toggle rate, a probability of logic high value, an average mode power, etc., e.g., for at least the portion of the emulation workload (e.g., for a pre-designated time slice and/or for a time slice that is flagged as of interest of an operator or another automated system), and so forth.

At 590, the processing system may present at least one power utilization estimate for the circuit design, where the at least one power utilization estimate for the circuit design is based upon the at least one logic level metric count. For instance, the at least one power utilization estimate may include a toggle rate, a probability of logic high value, an average mode power, etc., as described above. Alternatively, or in addition, the at least one power utilization estimate may include the at least one logic level metric count itself. Following 590, the method 500 proceeds to 595 where the method 500 ends.

It should be noted that method 500 may be expanded to include additional steps, or may be modified to replace steps with different steps, to combine steps, to omit steps, to perform steps in a different order, and so forth. For instance, in one example, the processing system may repeat one or more steps of the method 500, such as 510-590 for one or more updates to the circuit design and/or for one or more new, additional, and/or different circuit design(s), 540-590 for one or more additional workloads, and so forth. In one example, 520 may be part of or a sub-operation of 530. In one example, the method 500 may further include combining count data from multiple logic level metric count modules to a buffer (e.g., a ping-pong buffer) and/or offloading multiple logic level metric count modules and/or multiple buffers (from different FPGAs/PLDs) to a workstation, for example. In one example, aspects of the method 500 may be performed by the processing system in accordance with instructions from a non-transitory computer-readable medium storing such instructions as described below. In addition, in one example, the programmable logic device(s) associated with the method 500 may include a programmable logic device such as described in greater detail below. In one example, the method 500 may be expanded or modified to include steps, functions, and/or operations, or other features described in connection with the example(s) of FIG. 1-4 or 6-8, or as described elsewhere herein. Thus, these and other modifications are all contemplated within the scope of the present disclosure.

Thus, in one example, the present disclosure may include a processing device that may add at least one logic level metric count module to a circuit design, load the circuit design into an emulation system, and apply an emulation workload to the emulation system to which the circuit design is loaded. The processing device may then obtain at least one logic level metric count from the at least one logic level metric count module, the at least one logic level metric count associated with at least a portion of the emulation workload, and present at least one power utilization estimate for the circuit design, where the at least one power utilization estimate for the circuit design is based upon the at least one logic level metric count.

In addition, in one example, the present disclosure may include a programmable logic device (PLD) having a multiplexer that includes a plurality of inputs for a plurality of sample registers associated with a plurality of nodes of a circuit design (e.g., that is compiled and loaded onto the PLD) and a selection line to select an input of the plurality of inputs to pass to an output of the multiplexer. The PLD may include a previous value store coupled to the output of the multiplexer, to store a value of the output of the multiplexer from a current emulation clock cycle until a next emulation clock cycle of a plurality of emulation cycles of an emulation workload that is applied to the programmable logic device. The PLD may also include a toggle detector having a first input for the output of the multiplexer and a second input for an output of the previous value store, where the toggle detector is configured to output a logic high value when a first value on the output of the multiplexer is different from a second value on the output of the previous value store. The PDL may also include an incrementer unit coupled to the output of the toggle detector, where the incrementer unit is configured to increase a count for each polling clock cycle in which the output of the toggle detector is a logic high value. In one example, the programmable logic device may be configured to include the multiplexer, the previous value store, the toggle detector, and the incrementer unit. For instance, the circuit design may be modified to include design aspects for the multiplexer, the previous value store, the toggle detector, and the incrementer unit. The PLD may then be configured to include the multiplexer, the previous value store, the toggle detector, and the incrementer unit in accordance with a compilation of the circuit design that is modified.

In one example, the previous value store may include a number of storage bits that is at least as great as a number of the plurality of inputs of the multiplexer. In one example, the previous value store may include an address select input that is the same as the selection input of the multiplexer. In one example, the toggle detector may include an edge detector circuit. In one example, each sample register of the plurality of sample registers stores a value of a respective node of the plurality of nodes for each emulation clock cycle of the plurality of emulation clock cycles of the emulation workload. In addition, in one example, the multiplexer, the previous value store, the toggle detector, and the incrementer unit may be a first toggle count circuit, where the PLD may include a plurality of toggle count circuits including the first toggle count circuit. In such an example, the PLD may further include a buffer coupled the plurality of toggle count circuits that is configured to tally counts from a plurality of incrementer units of the plurality of toggle count circuits.

In another example, the present disclosure may alternatively or additionally include a non-transitory computer-readable medium storing a circuit design, which when loaded onto at least one programmable logic device, configures the at least one programmable logic device to include a multiplexer having a plurality of inputs for a plurality of sample registers associated with a plurality of nodes of the circuit design and a selection line to select an input of the plurality of inputs to pass to an output of the multiplexer, and an incrementer unit coupled to the output of the multiplexer, the incrementer unit configured to increase a count for each polling clock cycle in which the output of the multiplexer is a logic high value. In one example, each sample register of the plurality of sample registers may store a value of a respective node of the plurality of nodes for each emulation clock cycle of a plurality of emulation clock cycles of the emulation workload. In one example, the stored circuit design, when loaded onto the at least one programmable logic device, further configures the at least one programmable logic device to include a plurality of logic high count circuits/modules, and a buffer coupled the plurality of logic high count circuits that is configured to tally counts from a plurality of incrementer units of the plurality of logic high count circuits. In such an example, the multiplexer and the incrementer unit may be a first logic high count circuit of the plurality of logic high count circuits. In one example, the foregoing programmable logic device and non-transitory computer-readable medium may be used in connection with any one or more aspects of the example method 500 of FIG. 5.

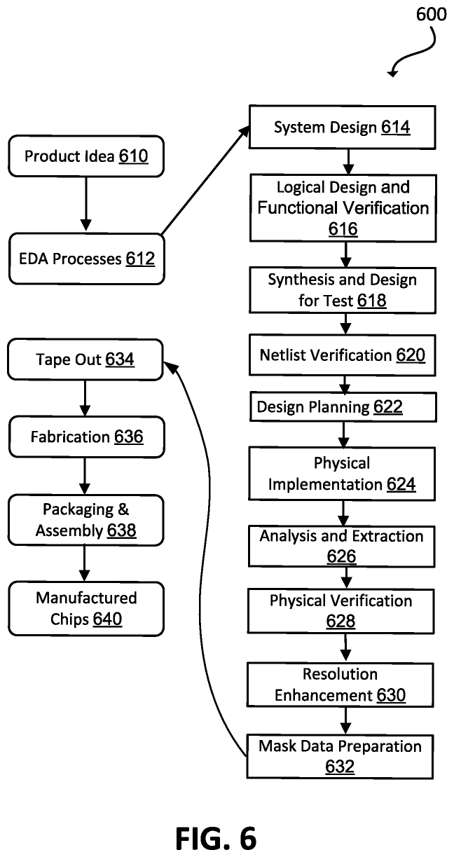

FIG. 6 illustrates an example set of processes 600 used during the design, verification, and fabrication of an article of manufacture such as an integrated circuit to transform and verify design data and instructions that represent the integrated circuit. Each of these processes can be structured and enabled as multiple modules or operations. The term ‘EDA’ signifies the term ‘Electronic Design Automation.’ These processes start with the creation of a product idea 610 with information supplied by a designer, information which is transformed to create an article of manufacture that uses a set of EDA processes 612. When the design is finalized, the design is taped-out 634, which is when artwork (e.g., geometric patterns) for the integrated circuit is sent to a fabrication facility to manufacture the mask set, which is then used to manufacture the integrated circuit. After tape-out, a semiconductor die is fabricated 636 and packaging and assembly processes 638 are performed to produce the finished integrated circuit 640.

Specifications for a circuit or electronic structure may range from low-level transistor material layouts to high-level description languages. A high-level of representation may be used to design circuits and systems, using a hardware description language (‘HDL’) such as VHDL, Verilog, System Verilog, SystemC, MyHDL or Open Vera. The HDL description can be transformed to a logic-level register transfer level (‘RTL’) description, a gate-level description, a layout-level description, or a mask-level description. Each lower representation level that is a more detailed description adds more useful details into the design description, for example, more details for the modules that include the description. The lower levels of representation that are more detailed descriptions can be generated by a computer, derived from a design library, or created by another design automation process. An example of a specification language at a lower level of representation language for specifying more detailed descriptions is SPICE, which is used for detailed descriptions of circuits with many analog components. Descriptions at each level of representation are enabled for use by the corresponding systems of that layer (e.g., a formal verification system). A design process may use a sequence depicted in FIG. 6. The described processes may be enabled by EDA products (or EDA systems).

During system design 614, functionality of an integrated circuit to be manufactured is specified. The design may be optimized for desired characteristics such as power consumption, performance, area (physical and/or lines of code), and reduction of costs, etc. Partitioning of the design into different types of modules or components can occur at this stage.

During logic design and functional verification 616, modules or components in the circuit are specified in one or more description languages and the specification is checked for functional accuracy. For example, the components of the circuit may be verified to generate outputs that match the requirements of the specification of the circuit or system being designed. Functional verification may use simulators and other programs such as testbench generators, static HDL checkers, and formal verifiers. In some embodiments, special systems of components referred to as ‘emulators’ or ‘prototyping systems’ are used to speed up the functional verification.

During synthesis and design for test 618, HDL code is transformed to a netlist. In some embodiments, a netlist may be a graph structure where edges of the graph structure represent components of a circuit and where the nodes of the graph structure represent how the components are interconnected. Both the HDL code and the netlist are hierarchical articles of manufacture that can be used by an EDA product to verify that the integrated circuit, when manufactured, performs according to the specified design. The netlist can be optimized for a target semiconductor manufacturing technology. Additionally, the finished integrated circuit may be tested to verify that the integrated circuit satisfies the requirements of the specification.

During netlist verification 620, the netlist is checked for compliance with timing constraints and for correspondence with the HDL code. During design planning 622, an overall floor plan for the integrated circuit is constructed and analyzed for timing and top-level routing.

During layout or physical implementation 624, physical placement (positioning of circuit components such as transistors or capacitors) and routing (connection of the circuit components by multiple conductors) occurs, and the selection of cells from a library to enable specific logic functions can be performed. As used herein, the term ‘cell’ may specify a set of transistors, other components, and interconnections that provides a Boolean logic function (e.g., AND, OR, NOT, XOR) or a storage function (such as a flipflop or latch). As used herein, a circuit ‘block’ may refer to two or more cells. Both a cell and a circuit block can be referred to as a module or component and are enabled as both physical structures and in simulations. Parameters are specified for selected cells (based on ‘standard cells’) such as size and made accessible in a database for use by EDA products.

During analysis and extraction 626, the circuit function is verified at the layout level, which permits refinement of the layout design. During physical verification 628, the layout design is checked to ensure that manufacturing constraints are correct, such as DRC constraints, electrical constraints, lithographic constraints, and that circuitry function matches the HDL design specification. During resolution enhancement 630, the geometry of the layout is transformed to improve how the circuit design is manufactured.

During tape-out, data is created to be used (after lithographic enhancements are applied if appropriate) for production of lithography masks. During mask data preparation 632, the ‘tape-out’ data is used to produce lithography masks that are used to produce finished integrated circuits.

A storage subsystem of a computer system (such as computer system 800 of FIG. 8) may be used to store the programs and data structures that are used by some or all of the EDA products described herein, and products used for development of cells for the library and for physical and logical design that use the library.

FIG. 7 depicts a diagram of an example emulation environment 700. An emulation environment 700 may be configured to verify the functionality of a circuit design. The emulation environment 700 may include a host system 707 (e.g., a computer that is part of an EDA system) and an emulation system 702 (e.g., a set of programmable devices such as Field Programmable Gate Arrays (FPGAs) or processors). The host system generates data and information by using a compiler 710 to structure the emulation system to emulate a circuit design. A circuit design to be emulated is also referred to as a Design Under Test (‘DUT’) where data and information from the emulation are used to verify the functionality of the DUT.

The host system 707 may include one or more processors. In the embodiment where the host system includes multiple processors, the functions described herein as being performed by the host system can be distributed among the multiple processors. The host system 707 may include a compiler 710 to transform specifications written in a description language that represents a DUT and to produce data (e.g., binary data) and information that is used to structure the emulation system 702 to emulate the DUT. The compiler 710 can transform, change, restructure, add new functions to, and/or control the timing of the DUT.

The host system 707 and emulation system 702 exchange data and information using signals carried by an emulation connection. The connection can be, but is not limited to, one or more electrical cables such as cables with pin structures compatible with the Recommended Standard 232 (RS232) or universal serial bus (USB) protocols. The connection can be a wired communication medium or network such as a local area network or a wide area network such as the Internet. The connection can be a wireless communication medium or a network with one or more points of access using a wireless protocol such as BLUETOOTH or IEEE 802.11. The host system 707 and emulation system 702 can exchange data and information through a third device such as a network server.

The emulation system 702 includes multiple FPGAs (or other modules) such as FPGAs 704₁ and 704₂ as well as additional FPGAs up to 704_{N}. Each FPGA can include one or more FPGA interfaces through which the FPGA is connected to other FPGAs (and potentially other emulation components) for the FPGAs to exchange signals. An FPGA interface can be referred to as an input/output pin or an FPGA pad. While an emulator may include FPGAs, embodiments of emulators can include other types of logic blocks instead of, or along with, the FPGAs for emulating DUTs. For example, the emulation system 702 can include custom FPGAs, specialized ASICs for emulation or prototyping, memories, and input/output devices.

A programmable device can include an array of programmable logic blocks and a hierarchy of interconnections that can enable the programmable logic blocks to be interconnected according to the descriptions in the HDL code. Each of the programmable logic blocks can enable complex combinational functions or enable logic gates such as AND, and XOR logic blocks. In some embodiments, the logic blocks also can include memory elements/devices, which can be simple latches, flip-flops, or other blocks of memory. Depending on the length of the interconnections between different logic blocks, signals can arrive at input terminals of the logic blocks at different times and thus may be temporarily stored in the memory elements/devices.

FPGAs 704₁-704_{N} may be placed onto one or more boards 712₁ and 712₂ as well as additional boards through 712_{M}. Multiple boards can be placed into an emulation unit 714₁. The boards within an emulation unit can be connected using the backplane of the emulation unit or any other types of connections. In addition, multiple emulation units (e.g., 714₁-714_{K}) can be connected to each other by cables or any other means to form a multi-emulation unit system.

For a DUT that is to be emulated, the host system 707 transmits one or more bit files to the emulation system 702. The bit files may specify a description of the DUT and may further specify partitions of the DUT created by the host system 707 with trace and injection logic, mappings of the partitions to the FPGAs of the emulator, and design constraints. Using the bit files, the emulator structures the FPGAs to perform the functions of the DUT. In some embodiments, one or more FPGAs of the emulators may have the trace and injection logic built into the silicon of the FPGA. In such an embodiment, the FPGAs may not be structured by the host system to emulate trace and injection logic.

The host system 707 receives a description of the DUT that is to be emulated. In some embodiments, the DUT description is in a description language (e.g., a register transfer language (RTL)). In some embodiments, the DUT description is in netlist level files or a mix of netlist level files and HDL files. If part of the DUT description or the entire DUT description is in an HDL, then the host system can synthesize the DUT description to create a gate level netlist using the DUT description. A host system can use the netlist of the DUT to partition the DUT into multiple partitions where one or more of the partitions include trace and injection logic. The trace and injection logic traces interface signals that are exchanged via the interfaces of an FPGA. Additionally, the trace and injection logic can inject traced interface signals into the logic of the FPGA. The host system maps each partition to an FPGA of the emulator. In some embodiments, the trace and injection logic is included in select partitions for a group of FPGAs. The trace and injection logic can be built into one or more of the FPGAs of an emulator. The host system can synthesize multiplexers to be mapped into the FPGAs. The multiplexers can be used by the trace and injection logic to inject interface signals into the DUT logic.

The host system creates bit files describing each partition of the DUT and the mapping of the partitions to the FPGAs. For partitions in which trace and injection logic is included, the bit files also describe the logic that is included. The bit files can include place and route information and design constraints. The host system stores the bit files and information describing which FPGAs are to emulate each component of the DUT (e.g., to which FPGAs each component is mapped).

Upon request, the host system transmits the bit files to the emulator. The host system signals the emulator to start the emulation of the DUT. During emulation of the DUT or at the end of the emulation, the host system receives emulation results from the emulator through the emulation connection. Emulation results are data and information generated by the emulator during the emulation of the DUT which include interface signals and states of interface signals that have been traced by the trace and injection logic of each FPGA. The host system can store the emulation results and/or transmit the emulation results to another processing system.

After emulation of the DUT, a circuit designer can request to debug a component of the DUT. If such a request is made, the circuit designer can specify a time period of the emulation to debug. The host system identifies which FPGAs are emulating the component using the stored information. The host system retrieves stored interface signals associated with the time period and traced by the trace and injection logic of each identified FPGA. The host system signals the emulator to re-emulate the identified FPGAs. The host system transmits the retrieved interface signals to the emulator to re-emulate the component for the specified time period. The trace and injection logic of each identified FPGA injects its respective interface signals received from the host system into the logic of the DUT mapped to the FPGA. In case of multiple re-emulations of an FPGA, merging the results produces a full debug view.

The host system receives, from the emulation system, signals traced by logic of the identified FPGAs during the re-emulation of the component. The host system stores the signals received from the emulator. The signals traced during the re-emulation can have a higher sampling rate than the sampling rate during the initial emulation. For example, in the initial emulation a traced signal can include a saved state of the component every X milliseconds. However, in the re-emulation the traced signal can include a saved state every Y milliseconds where Y is less than X. If the circuit designer requests to view a waveform of a signal traced during the re-emulation, the host system can retrieve the stored signal and display a plot of the signal. For example, the host system can generate a waveform of the signal. Afterwards, the circuit designer can request to re-emulate the same component for a different time period or to re-emulate another component.

The host system 707 and/or the compiler 710 may include sub-systems such as, but not limited to, a design synthesizer sub-system, a mapping sub-system, a run time sub-system, a results sub-system, a debug sub-system, a waveform sub-system, and a storage sub-system. These sub-systems can be structured and enabled as individual or multiple modules or two or more may be structured as a module. Together these sub-systems structure the emulator and monitor the emulation results.

The design synthesizer sub-system transforms the HDL that is representing a DUT 705 into gate level logic. For a DUT that is to be emulated, the design synthesizer sub-system receives a description of the DUT. If the description of the DUT is fully or partially in HDL (e.g., RTL or other level of representations), the design synthesizer sub-system synthesizes the HDL of the DUT to create a gate-level netlist with a description of the DUT in terms of gate level logic.

The mapping sub-system partitions DUTs and maps the partitions into emulator FPGAs. The mapping sub-system partitions a DUT at the gate level into a number of partitions using the netlist of the DUT. For each partition, the mapping sub-system retrieves a gate level description of the trace and injection logic and adds the logic to the partition. As described above, the trace and injection logic included in a partition is used to trace signals exchanged via the interfaces of an FPGA to which the partition is mapped (trace interface signals). The trace and injection logic can be added to the DUT prior to the partitioning. For example, the trace and injection logic can be added by the design synthesizer sub-system prior to or after the synthesizing the HDL of the DUT.

In addition to including the trace and injection logic, the mapping sub-system can include additional tracing logic in a partition to trace the states of certain DUT components that are not traced by the trace and injection. The mapping sub-system can include the additional tracing logic in the DUT prior to the partitioning or in partitions after the partitioning. The design synthesizer sub-system can include the additional tracing logic in an HDL description of the DUT prior to synthesizing the HDL description.

The mapping sub-system maps each partition of the DUT to an FPGA of the emulator. For partitioning and mapping, the mapping sub-system uses design rules, design constraints (e.g., timing or logic constraints), and information about the emulator. For components of the DUT, the mapping sub-system stores information in the storage sub-system describing which FPGAs are to emulate each component.

Using the partitioning and the mapping, the mapping sub-system generates one or more bit files that describe the created partitions and the mapping of logic to each FPGA of the emulator. The bit files can include additional information such as constraints of the DUT and routing information of connections between FPGAs and connections within each FPGA. The mapping sub-system can generate a bit file for each partition of the DUT and can store the bit file in the storage sub-system. Upon request from a circuit designer, the mapping sub-system transmits the bit files to the emulator, and the emulator can use the bit files to structure the FPGAs to emulate the DUT.

If the emulator includes specialized ASICs that include the trace and injection logic, the mapping sub-system can generate a specific structure that connects the specialized ASICs to the DUT. In some embodiments, the mapping sub-system can save the information of the traced/injected signal and where the information is stored on the specialized ASIC.

The run time sub-system controls emulations performed by the emulator. The run time sub-system can cause the emulator to start or stop executing an emulation. Additionally, the run time sub-system can provide input signals and data to the emulator. The input signals can be provided directly to the emulator through the connection or indirectly through other input signal devices. For example, the host system can control an input signal device to provide the input signals to the emulator. The input signal device can be, for example, a test board (directly or through cables), signal generator, another emulator, or another host system.

The results sub-system processes emulation results generated by the emulator. During emulation and/or after completing the emulation, the results sub-system receives emulation results from the emulator generated during the emulation. The emulation results include signals traced during the emulation. Specifically, the emulation results include interface signals traced by the trace and injection logic emulated by each FPGA and can include signals traced by additional logic included in the DUT. Each traced signal can span multiple cycles of the emulation. A traced signal includes multiple states and each state is associated with a time of the emulation. The results sub-system stores the traced signals in the storage sub-system. For each stored signal, the results sub-system can store information indicating which FPGA generated the traced signal.

The debug sub-system allows circuit designers to debug DUT components. After the emulator has emulated a DUT and the results sub-system has received the interface signals traced by the trace and injection logic during the emulation, a circuit designer can request to debug a component of the DUT by re-emulating the component for a specific time period. In a request to debug a component, the circuit designer identifies the component and indicates a time period of the emulation to debug. The circuit designer's request can include a sampling rate that indicates how often states of debugged components should be saved by logic that traces signals.

The debug sub-system identifies one or more FPGAs of the emulator that are emulating the component using the information stored by the mapping sub-system in the storage sub-system. For each identified FPGA, the debug sub-system retrieves, from the storage sub-system, interface signals traced by the trace and injection logic of the FPGA during the time period indicated by the circuit designer. For example, the debug sub-system retrieves states traced by the trace and injection logic that are associated with the time period.

The debug sub-system transmits the retrieved interface signals to the emulator. The debug sub-system instructs the debug sub-system to use the identified FPGAs and for the trace and injection logic of each identified FPGA to inject its respective traced signals into logic of the FPGA to re-emulate the component for the requested time period. The debug sub-system can further transmit the sampling rate provided by the circuit designer to the emulator so that the tracing logic traces states at the proper intervals.

To debug the component, the emulator can use the FPGAs to which the component has been mapped. Additionally, the re-emulation of the component can be performed at any point specified by the circuit designer.

For an identified FPGA, the debug sub-system can transmit instructions to the emulator to load multiple emulator FPGAs with the same configuration of the identified FPGA. The debug sub-system additionally signals the emulator to use the multiple FPGAs in parallel. Each FPGA from the multiple FPGAs is used with a different time window of the interface signals to generate a larger time window in a shorter amount of time. For example, the identified FPGA can require an hour or more to use a certain amount of cycles. However, if multiple FPGAs have the same data and structure of the identified FPGA and each of these FPGAs runs a subset of the cycles, the emulator can require a few minutes for the FPGAs to collectively use all the cycles.

A circuit designer can identify a hierarchy or a list of DUT signals to re-emulate. To enable this, the debug sub-system determines the FPGA needed to emulate the hierarchy or list of signals, retrieves the necessary interface signals, and transmits the retrieved interface signals to the emulator for re-emulation. Thus, a circuit designer can identify any element (e.g., component, device, or signal) of the DUT to debug/re-emulate.

The waveform sub-system generates waveforms using the traced signals. If a circuit designer requests to view a waveform of a signal traced during an emulation run, the host system retrieves the signal from the storage sub-system. The waveform sub-system displays a plot of the signal. For one or more signals, when the signals are received from the emulator, the waveform sub-system can automatically generate the plots of the signals.

FIG. 8 illustrates an example machine of a computer system 800 within which a set of instructions, for causing the machine to perform any one or more of the methodologies discussed herein, may be executed. In alternative implementations, the machine may be connected (e.g., networked) to other machines in a LAN, an intranet, an extranet, and/or the Internet. The machine may operate in the capacity of a server or a client machine in client-server network environment, as a peer machine in a peer-to-peer (or distributed) network environment, or as a server or a client machine in a cloud computing infrastructure or environment.

The machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 800 includes a processing device 802, a main memory 804 (e.g., read-only memory (ROM), flash memory, dynamic random access memory (DRAM) such as synchronous DRAM (SDRAM), a static memory 806 (e.g., flash memory, static random access memory (SRAM), etc.), and a data storage device 818, which communicate with each other via a bus 830.

Processing device 802 represents one or more processors such as a microprocessor, a central processing unit, or the like. More particularly, the processing device may be complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 802 may also be one or more special-purpose processing devices such as an application specific integrated circuit (ASIC), a field programmable gate array (FPGA), a digital signal processor (DSP), network processor, or the like. The processing device 802 may be configured to execute instructions 826 for performing the operations and steps described herein.

The computer system 800 may further include a network interface device 808 to communicate over the network 820. The computer system 800 also may include a video display unit 810 (e.g., a liquid crystal display (LCD) or a cathode ray tube (CRT)), an alphanumeric input device 812 (e.g., a keyboard), a cursor control device 814 (e.g., a mouse), a graphics processing unit 822, a signal generation device 816 (e.g., a speaker), graphics processing unit 822, video processing unit 828, and audio processing unit 832.

The data storage device 818 may include a machine-readable storage medium 824 (also known as a non-transitory computer-readable medium) on which is stored one or more sets of instructions 826 or software embodying any one or more of the methodologies or functions described herein. The instructions 826 may also reside, completely or at least partially, within the main memory 804 and/or within the processing device 802 during execution thereof by the computer system 800, the main memory 804 and the processing device 802 also constituting machine-readable storage media.

In some implementations, the instructions 826 include instructions to implement functionality corresponding to the present disclosure. While the machine-readable storage medium 824 is shown in an example implementation to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine and the processing device 802 to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm may be a sequence of operations leading to a desired result. The operations are those requiring physical manipulations of physical quantities. Such quantities may take the form of electrical or magnetic signals capable of being stored, combined, compared, and otherwise manipulated. Such signals may be referred to as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the present disclosure, it is appreciated that throughout the description, certain terms refer to the action and processes of a computer system, or similar electronic computing device, that manipulates and transforms data represented as physical (electronic) quantities within the computer system's registers and memories into other data similarly represented as physical quantities within the computer system memories or registers or other such information storage devices.

The present disclosure also relates to an apparatus for performing the operations herein. This apparatus may be specially constructed for the intended purposes, or it may include a computer selectively activated or reconfigured by a computer program stored in the computer. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various other systems may be used with programs in accordance with the teachings herein, or it may prove convenient to construct a more specialized apparatus to perform the method. In addition, the present disclosure is not described with reference to any particular programming language. It will be appreciated that a variety of programming languages may be used to implement the teachings of the disclosure as described herein.

The present disclosure may be provided as a computer program product, or software, that may include a machine-readable medium having stored thereon instructions, which may be used to program a computer system (or other electronic devices) to perform a process according to the present disclosure. A machine-readable medium includes any mechanism for storing information in a form readable by a machine (e.g., a computer). For example, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing disclosure, implementations of the disclosure have been described with reference to specific example implementations thereof. It will be evident that various modifications may be made thereto without departing from the broader spirit and scope of implementations of the disclosure as set forth in the following claims. Where the disclosure refers to some elements in the singular tense, more than one element can be depicted in the figures and like elements are labeled with like numerals. The present disclosure and drawings are, accordingly, to be regarded in an illustrative sense rather than a restrictive sense.

What is claimed is:

1. A method comprising:
adding at least one logic level metric count module to a circuit design;
loading, by a processing device, the circuit design into an emulation system;
applying, by the processing device, an emulation workload to the emulation system to which the circuit design is loaded;
obtaining at least one logic level metric count from the at least one logic level metric count module, the at least one logic level metric count associated with at least a portion of the emulation workload; and
presenting at least one power utilization estimate for the circuit design, wherein the at least one power utilization estimate for the circuit design is based upon the at least one logic level metric count.

2. The method of claim 1, wherein the at least one logic level metric count comprises:
a toggle count of signals at one or more nodes of the circuit design; or
a count of instances of the signals being at logic level high at the one or more nodes of the circuit design.

3. The method of claim 1, wherein the at least one logic level metric count module includes:
a multiplexer having:
a plurality of inputs for a plurality of sample registers associated with a plurality of nodes of the circuit design; and
a selection input to select an input of the plurality of inputs to pass to an output of the multiplexer; and
an incrementer unit coupled to the output of the multiplexer, wherein the incrementer unit increases a count for each polling clock cycle in which the output of the multiplexer is a logic high value.

4. The method of claim 3, wherein each sample register of the plurality of sample registers stores a value of a respective node of the plurality of nodes for each emulation clock cycle of a plurality of emulation clock cycles of the emulation workload.

5. The method of claim 1, wherein the at least one logic level metric count module includes:
a multiplexer having:
a plurality of inputs for a plurality of sample registers associated with a plurality of nodes of the circuit design; and
a selection line to select an input of the plurality of inputs to pass to an output of the multiplexer;
a previous value store coupled to the output of the multiplexer, to store a value of the output of the multiplexer from a current emulation clock cycle until a next emulation clock cycle of a plurality of emulation cycles of the emulation workload;
a toggle detector having a first input for the output of the multiplexer and a second input for an output of the previous value store, where the toggle detector outputs a logic high value when a first value on the output of the multiplexer is different from a second value on the output of the previous value store; and
an incrementer unit coupled to the output of the toggle detector, wherein the incrementer unit increases a count for each polling clock cycle in which the output of the toggle detector is a logic high value.

6. The method of claim 5, wherein the previous value store includes a number of storage bits that is at least as great as a number of the plurality of inputs of the multiplexer, wherein the previous value store includes an address select input that is the same as the selection line of the multiplexer.

7. The method of claim 5, wherein the toggle detector comprises an edge detector circuit.

8. The method of claim 5, wherein each sample register of the plurality of sample registers stores a value of a respective node of the plurality of nodes for each emulation clock cycle of the plurality of emulation clock cycles of the emulation workload.

9. The method of claim 1, wherein the at least one power utilization estimate comprises:
the at least one logic level metric count;
a toggle rate;
a probability of logic high value; or
an average mode power.

10. A programmable logic device comprising:
a multiplexer having:
a plurality of inputs for a plurality of sample registers associated with a plurality of nodes of a circuit design; and
a selection line to select an input of the plurality of inputs to pass to an output of the multiplexer;
a previous value store coupled to the output of the multiplexer, to store a value of the output of the multiplexer from a current emulation clock cycle until a next emulation clock cycle of a plurality of emulation cycles of an emulation workload that is applied to the programmable logic device;
a toggle detector having a first input for the output of the multiplexer and a second input for an output of the previous value store, where the toggle detector is configured to output a logic high value when a first value on the output of the multiplexer is different from a second value on the output of the previous value store; and
an incrementer unit coupled to the output of the toggle detector, wherein the incrementer unit is configured to increase a count for each polling clock cycle in which the output of the toggle detector is a logic high value.

11. The programmable logic device of claim 10, wherein the programmable logic device is configured to include the multiplexer, the previous value store, the toggle detector, and the incrementer unit.

12. The programmable logic device of claim 10, wherein the circuit design is modified to include design aspects for the multiplexer, the previous value store, the toggle detector, and the incrementer unit, and wherein the programmable logic device is configured to include the multiplexer, the previous value store, the toggle detector, and the incrementer unit in accordance with a compilation of the circuit design that is modified.

13. The programmable logic device of claim 10, wherein the previous value store includes a number of storage bits that is at least as great as a number of the plurality of inputs of the multiplexer.

14. The programmable logic device of claim 13, wherein the previous value store includes an address select input that is the same as the selection input of the multiplexer.

15. The programmable logic device of claim 10, wherein the toggle detector comprises an edge detector circuit.

16. The programmable logic device of claim 10, wherein each sample register of the plurality of sample registers stores a value of a respective node of the plurality of nodes for each emulation clock cycle of the plurality of emulation clock cycles of the emulation workload.

17. The programmable logic device of claim 10, wherein the multiplexer, the previous value store, the toggle detector, and the incrementer unit comprises a first toggle count circuit, wherein the programmable logic device comprises a plurality of toggle count circuits including the first toggle count circuit, and wherein the programmable logic device further comprises a buffer coupled the plurality of toggle count circuits that is configured to tally counts from a plurality of incrementer units of the plurality of toggle count circuits.

18. A non-transitory computer-readable medium comprising a stored circuit design, which when loaded onto at least one programmable logic device, configure the at least one programmable logic device to include:
a multiplexer having:
a plurality of inputs for a plurality of sample registers associated with a plurality of nodes of the stored circuit design; and
a selection line to select an input of the plurality of inputs to pass to an output of the multiplexer; and
an incrementer unit coupled to the output of the multiplexer, wherein the incrementer unit is configured to increase a count for each polling clock cycle in which the output of the multiplexer is a logic high value.

19. The non-transitory computer-readable medium of claim 18, wherein each sample register of the plurality of sample registers stores a value of a respective node of the plurality of nodes for each emulation clock cycle of a plurality of emulation clock cycles of an emulation workload.

20. The non-transitory computer-readable medium of claim 18, and wherein the stored circuit design, when loaded onto the at least one programmable logic device, further configures the at least one programmable logic device to include:
a plurality of logic high count circuits, wherein the multiplexer and the incrementer unit comprise a first logic high count circuit of the plurality of logic high count circuits; and
a buffer coupled the plurality of logic high count circuits that is configured to tally counts from a plurality of incrementer units of the plurality of logic high count circuits.
